(19) United States
(12) Patent Application Publication
(10) Pub. No.: US 2011/0101397 A1
(43) Pub. Date: May 5, 2011

(54) LIGHT EMITTING DIODE PACKAGE HAVING LENS

(75) Inventors: Hwan-Kuk YUH, Gyeonggi-Do (KR); Young-Boo MOON, Gyeonggi-Do (KR); Sung-Chul CHOI, Gyeonggi-Do (KR)

(73) Assignee: THELEDS CO., LTD., Gyeonggi-Do (KR)

(21) Appl. No.: 12/908,422

(22) Filed: Oct. 20, 2010

(30) Foreign Application Priority Data
Nov. 3, 2009 (KR) 10-2009-0105437

(51) Int. Cl. H01L 33/48

(52) U.S. Cl. 257/98; 257/E33.073

(57) ABSTRACT

Provided is a light emitting diode package. The light emitting diode package includes a package body, a light emitting diode chip, and a package lens. The light emitting diode chip is installed in the package body. The package lens is installed in the package body to cover the light emitting diode chip, and is formed to have a shape corresponding to a radiation angle pattern of the light emitting diode chip.

### CROSS-REFERENCE TO RELATED APPLICATION

This application claims priority to Korean Patent Application No. 2009-0105437 filed on Nov. 3, 2009 and all the benefits accruing therefrom under 35 U.S.C. §119, the contents of which are incorporated by reference in their entirety.

### BACKGROUND

The present disclosure relates to a light emitting diode (LED) package including a lens, and more particularly, to an LED package capable of controlling a radiation angle pattern through a lens.

The light emitting diode (LED) market has grown based on a low-power LED used in keypads of portable communication apparatuses such as mobile phones, or small-size electric home appliances, and back light units (BLUs) of liquid crystal displays (LCDs). In recent years, as the necessity of high-power and high-efficiency light sources used in interior lighting, exterior lighting, automobile interior/exterior decoration, and BLUs of large-size LCD arises, the focus of the LED market is also shifting to high-power products.

A spherical light emitting having the same flux at all solid angles is ideal in a radiation angle pattern of an LED chip, but an actual radiation angle pattern becomes biased to a specific region. Thus, since light is intensively irradiated on a certain phosphor coating region in an LED package, and light is hardly irradiated on other phosphor coating regions, this becomes the cause of reduction of the optical conversion efficiency due to phosphor.

In application fields that require an LED package having a broad radiation angle pattern like BLU, lighting, and streetlight, the LED package includes a package lens covering an LED chip to show a high efficiency. The radiation angle pattern of the LED package is adjusted through such a package lens.

FIGS. 1 through 3 are diagrams illustrating radiation angle patterns of light emitting diode (LED) packages including related art package lenses.

As shown in FIGS. 1 through 3, light emitting from an LED chip 10 is emitted to the outside through package lenses 20, 30 and 40. In the package lens 20 shown in FIG. 1, the radiation angle pattern has a lambertian distribution. In the package lens 30 shown in FIG. 2, the radiation angle pattern has a batwing distribution. In the package lens 40 shown in FIG. 3, the radiation angle pattern has a side-emitting distribution.

Thus, if the package lenses are used, the radiation angle pattern of the LED package can be adjusted. However, if the radiation angle pattern of the LED chip and the shape of the lens do not match each other, the optical efficiency may be reduced by the package lenses.

### SUMMARY

The present disclosure provides a light emitting diode (LED) package having a desired radiation angle pattern without a reduction of the optical efficiency even when a package lens is used.

According to an exemplary embodiment, a light emitting diode package includes: a package body; a light emitting diode chip installed in the package body; and a package lens installed in the package body to cover the light emitting diode chip, and formed to have a shape corresponding to a radiation angle pattern of the light emitting diode chip.

In some embodiments, the light emitting diode chip may include a substrate and a light emitting device disposed on the substrate, and at least one of side surfaces of the substrate may incline to a top surface of the substrate.

In other embodiments, an unevenness may be formed on the top surface of the substrate.

### BRIEF DESCRIPTION OF THE DRAWINGS

Exemplary embodiments can be understood in more detail from the following description taken in conjunction with the accompanying drawings, in which:

FIGS. 1 through 3 are diagrams illustrating radiation angle patterns of light emitting diode (LED) packages including related art package lenses;

FIGS. 4 through 7 are diagrams illustrating examples in which the side surface of a substrate forming an LED chip inclines to the top surface of the substrate, and a radiation angle pattern of the LED chip according thereto;

FIGS. 8 through 10 are diagrams illustrating examples of unevenness on the top surface of a substrate forming an LED chip, and a radiation angle pattern of the LED chip according thereto;

FIG. 11 is a diagram illustrating an example in which the side surface of a substrate forming an LED chip inclines to the top surface of a substrate and unevenness is formed on the top surface of the substrate, and a radiation angle pattern of the LED chip according thereto;

FIG. 12 is a diagram illustrating an LED package according to an exemplary embodiment, in which the side surface of a substrate forming an LED chip inclines to the top surface of the substrate; and

FIG. 13 is a diagram illustrating an LED package according to another exemplary embodiment, in which unevenness is formed on the top surface of a substrate forming an LED chip.

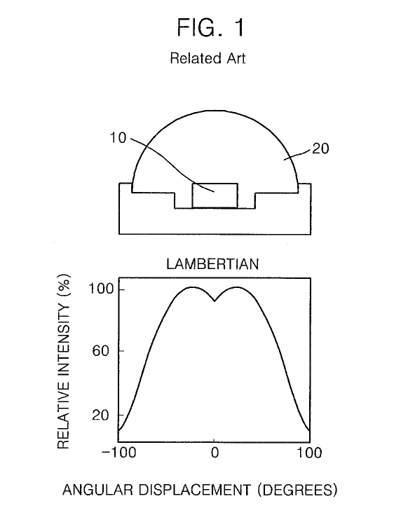

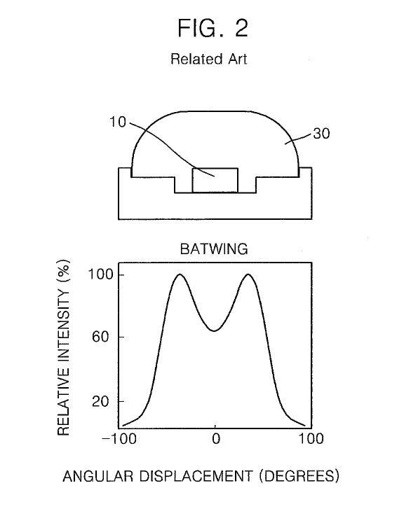

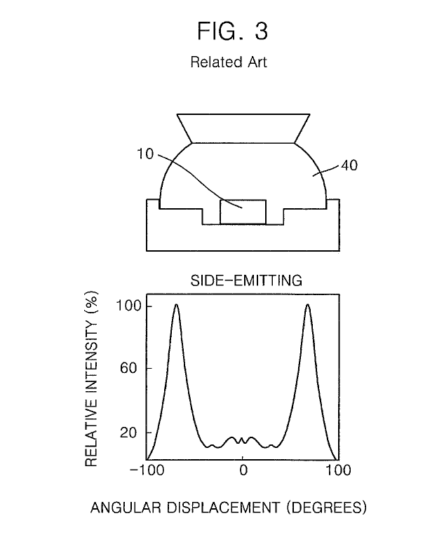

### DETAILED DESCRIPTION OF EMBODIMENTS

Hereinafter, exemplary embodiments of a light emitting diode (LED) package including a package lens according to the present invention will be described in detail with reference to the accompanying drawings. However, the present invention is not limited to embodiments disclosed herein, but implemented in various forms. These embodiments are provided to clarify the present invention and fully convey the scope of the present invention to those skilled in the art.

The present invention relates to an LED package including a package lens with a shape corresponding to a radiation angle pattern of an LED chip. Since the radiation angle pattern of the LED package according to the present invention agrees with the tendency of the radiation angle pattern of the LED chip, the radiation angle pattern of an LED chip will be first described. The radiation angle pattern of the LED chip may be changed by the shape of the section of a substrate and the shape of unevenness on the surface of the substrate forming the LED chip. Accordingly, it is possible to control the radiation angle pattern of the LED chip by appropriately selecting the shape of the section of the substrate and the shape of the unevenness on the surface of the substrate forming the LED chip.

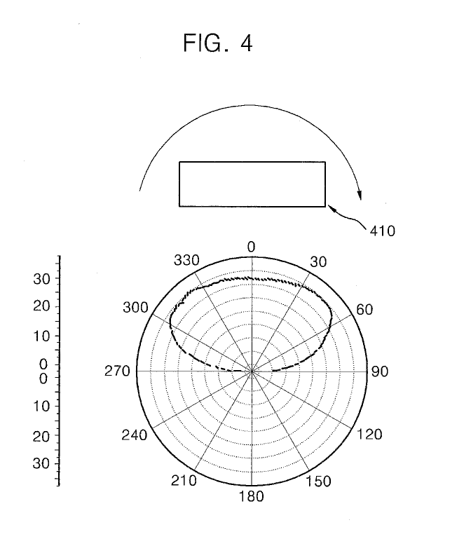

First, the radiation angle patterns of the LED chip according to the shape of the section of the substrate of the LED chip will be described. If the side surface of the substrate forming the LED chip is formed to incline to the top surface of the substrate, the radiation angle pattern of the LED chip is changed. FIGS. 4 through 7 are diagrams illustrating examples in which the side surface of a substrate forming an LED chip inclines to the top surface of the substrate, and a radiation angle pattern of the LED chip according thereto. A normal line direction perpendicular to the top surface of the substrate is shown as 0 degree in FIGS. 4 through 7.

FIG. 4 is a diagram illustrating a radiation angle pattern when the shape of the section of a substrate 410 forming an LED chip is typically rectangular.

As shown in FIG. 4, when the shape of the section of the substrate 410 of the LED chip is rectangular, the radiation angle pattern is concentrated on a portion in which an angle with respect to a normal line is about 60 degrees or less. That is, most light is emitted in an upward direction of the LED chip, and light is hardly emitted in a lateral direction of the LED chip.

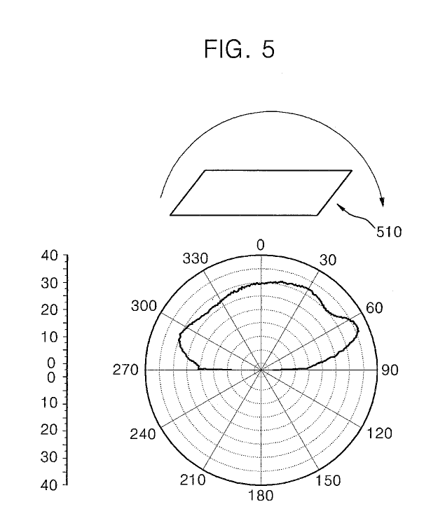

FIG. 5 is a diagram illustrating a radiation angle pattern when the shape of the section of a substrate 510 forming an LED chip is a parallelogram.

As shown in FIG. 5, when the shape of the section of the substrate 510 is a parallelogram, the radiation angle pattern may be broadly distributed as a whole compared to that of FIG. 4. Particularly, the most radiation angle pattern is distributed within an angle of about 60 degrees or less with respect to the normal line when the shape of the section of the substrate 410 is rectangular in FIG. 4, while a considerable portion of the radiation angle pattern is distributed even in an angle of about 60 degrees or more with respect to the normal line when the shape of the section of the substrate 510 is a parallelogram in FIG. 5. Also, the greatest intensity of radiation may be near about 60 degrees or more (near about 65 degrees) with respect to the normal line. Furthermore, the intensity of radiation outputted in a direction orthogonal to the normal line may be considerably increased compared to that of FIG. 4. Output light having the greatest intensity of radiation may be greater than that of FIG. 4 by about 30% or more.

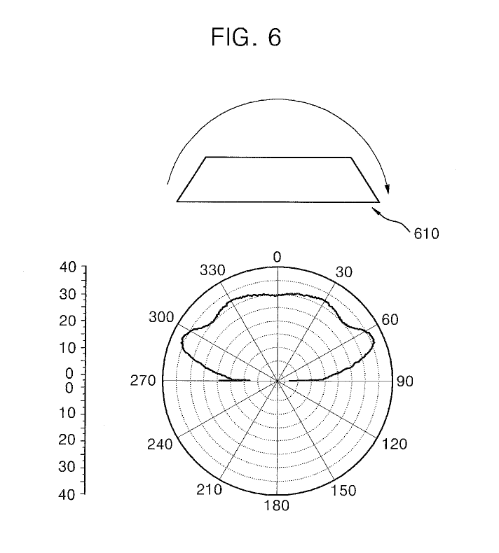

FIG. 6 is a diagram illustrating a radiation angle pattern when the shape of a substrate 610 forming an LED chip is a regular trapezoid (the length of the bottom side is greater than that of the top side).

As shown in FIG. 6, when the shape of the section of the substrate 610 is a regular trapezoid, the radiation angle pattern is broadly distributed as a whole compared to that of FIG. 4. Particularly, the most radiation angle pattern is distributed within an angle of about 60 degrees or less with respect to the normal line when the shape of the section of the substrate 410 is rectangular in FIG. 4, while a considerable portion of the radiation angle pattern is distributed in an angle of about 60 degrees or more with respect to the normal line when the shape of the section of the substrate 610 is a regular trapezoid in FIG. 6. Also, the greatest intensity of radiation is near about 60 degrees or more (near about 65 degrees and about 325 degrees) with respect to the normal line. Furthermore, the intensity of radiation outputted in a direction of the normal line may be considerably reduced compared to that of FIG. 4. Output light of the normal line direction may be less than about 80% of that of FIG. 4.

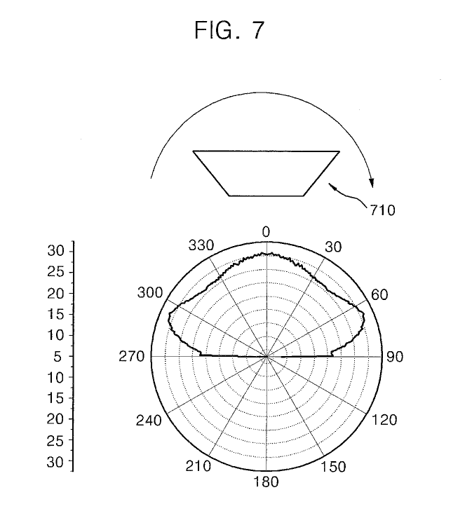

FIG. 7 is a diagram illustrating a radiation angle pattern when the shape of a substrate 710 forming an LED chip is an inverted trapezoid (the length of the top side is greater than that of the bottom side).

As shown in FIG. 7, when the shape of the section of the substrate 710 is an inverted trapezoid, the radiation angle pattern is broadly distributed as a whole compared to that of FIG. 4. Particularly, the most radiation angle pattern is distributed within an angle of about 60 degrees or less with respect to the normal line when the shape of the section of the substrate 410 is rectangular in FIG. 4, while a considerable portion of the radiation angle pattern is distributed in an angle of about 60 degrees or more with respect to the normal line when the shape of the section of the substrate 710 is an inverted trapezoid in FIG. 7. Also, the greatest intensity of radiation is near about 60 degrees or more (near about 65 degrees and about 325 degrees) with respect to the normal line. Furthermore, the intensity of radiation outputted in a direction orthogonal to the normal line may be considerably increased compared to that of FIG. 4. Output light having the greatest intensity of radiation may be greater than that of FIG. 4 by about 30% or more. The total intensity of radiation outputted at angles of about 60 degrees to about 90 degrees with respect to the normal line may be greater than about 30% of that outputted at angles of about 60 degrees or less. That is, the intensity of radiation outputted in a horizontal direction is considerably increased compared to that of FIG. 4.

As described with reference to FIGS. 4 through 7, the radiation angle pattern may be controlled by allowing the side surface of the substrate to be inclined to the top surface of the substrate. Particularly, as shown in FIG. 5, when the shape of the section of the substrate 510 is a parallelogram, the intensity of radiation may be concentrated on a lateral direction except the normal direction of the substrate. The distribution of the radiation angle pattern may be easily controlled by adjusting the inclination degree and direction of the side surface of the substrate. Since the intensity of radiation can be concentrated in a specific direction by controlling the inclination degree and direction of the side surface of the substrate, a semiconductor chip specialized to each product can be applied to various products.

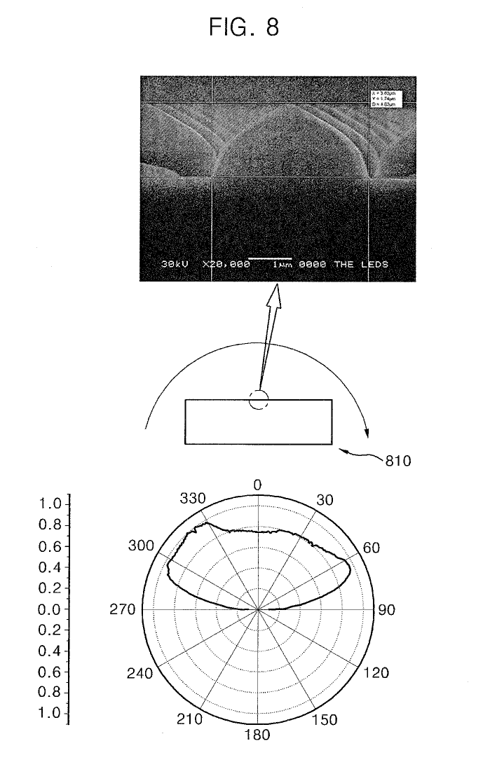

Hereinafter, a radiation angle pattern of an LED chip according to the shape of unevenness formed on the top surface of a substrate forming an LED will be described. When unevenness is formed on the top surface of the substrate forming the LED chip, the radiation angle pattern may be changed according to the shape of the unevenness. Examples of the unevenness and the radiation angle pattern of the LED chip are shown in FIGS. 8 through 10. A normal line direction perpendicular to the top surface of the substrate has been shown as 0 degree in FIGS. 8 through 10.

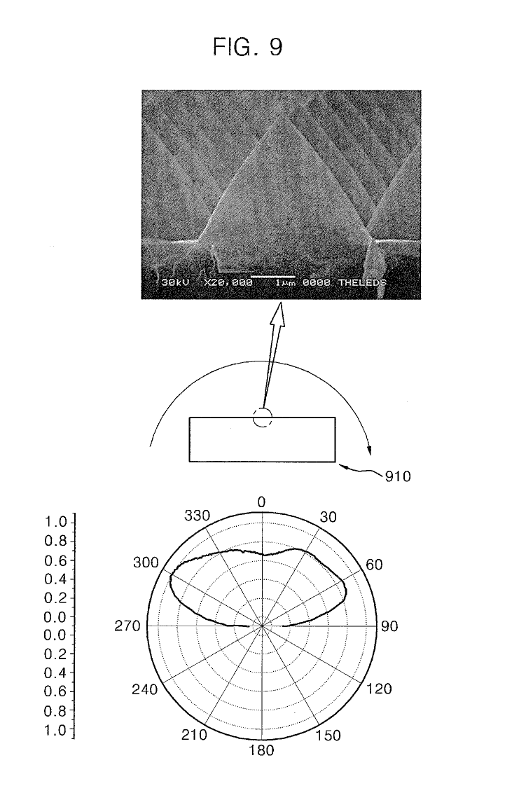

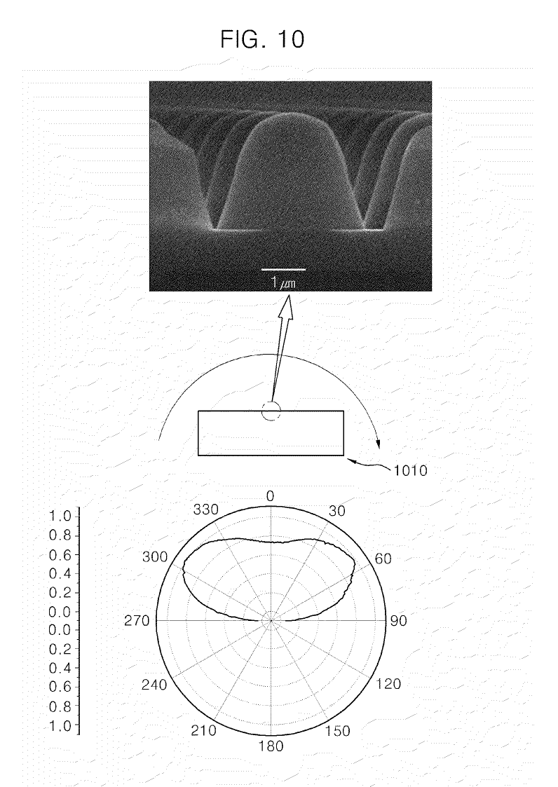

The shapes of the top surfaces of substrates 810, 910 and 1010 forming LED chips shown in FIGS. 8 through 10 may have square, rectangular, and parallelogram shapes, preferably, a rectangular shape. The shape of the section of the substrates 810, 910 and 1010 may have a rectangular shape. Unevenness may be formed on the top surfaces of the substrates 810, 910 and 1010 as shown scanning electron microscopy (SEM) photographs of FIGS. 8 through 10. FIG. 8 shows an unevenness having a bawl shape of sharp top and broad bottom. FIG. 9 shows an unevenness of a triangular pyramid shape. FIG. 10 shows an unevenness having a shape of flat top.

As shown in FIGS. 8 through 10, when the shape of the unevenness is changed, the radiation angle pattern of the LED chip may be changed. Particularly, the proportion of the intensity of radiation of a normal line direction of the substrates 810, 910 and 1010 may be considerably reduced compared to the case where the unevenness is not formed. That is, the intensity of radiation of the normal line direction may be adjusted by forming unevenness on the top surfaces of the substrates 810, 910 and 1010. Particularly, the radiation angle pattern may be controlled by adjusting the shape of the unevenness as shown in FIGS. 8 through 10. Although not shown in the drawings, if the size, density, and distribution of the unevenness are adjusted, it is possible to easily control the radiation angle pattern. When the unevenness is densely formed on the substrate, the intensity of radiation in the normal line direction of the substrate may increase. When the unevenness is sparsely formed on the substrate, the intensity of radiation in the normal line direction of the substrate may be reduced.

Also, since the intensity of radiation is concentrated in a specific direction by adjusting the shape, size, density, and distribution of the unevenness as occasion demands, a semiconductor chip specialized to each product may be applied to various products.

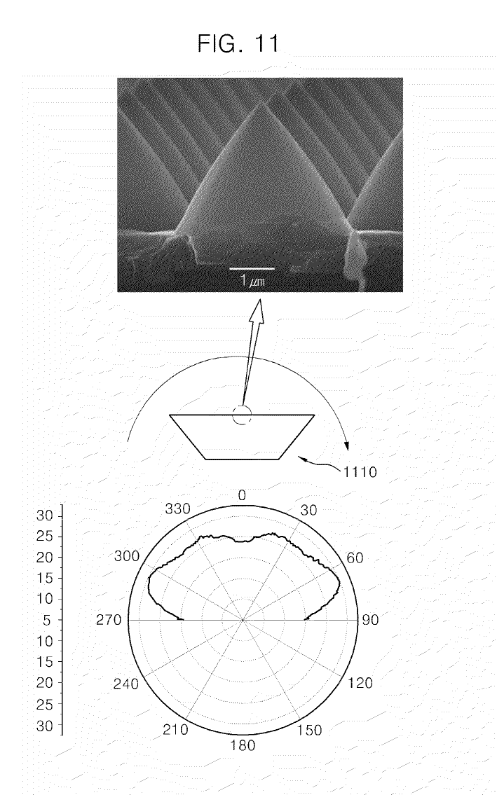

An example in which the side surface of a substrate forming an LED chip inclines to the top surface of the substrate and an unevenness is formed on the top surface of the substrate, and a radiation angle pattern of the LED chip according thereto are shown in FIG. 11. That is, FIG. 11 shows a radiation angle pattern when the shape of the section of a substrate 1110 is an inverted trapezoid as shown in FIG. 7, and an unevenness having a triangular pyramid shape is formed on the top surface of the substrate 1110 as shown in FIG. 9.

The radiation angle pattern may be broadly distributed as shown in FIG. 11, and may be uniformly distributed without being biased to a specific angle. That is, the intensity of radiation of a normal line direction (vertical direction) of the substrate 1110 may be relatively small, and the intensity of radiation of a direction crossing the normal line (horizontal direction) may be relatively great. Accordingly, if the inclination degree and inclination direction of the side surface of the substrate 1110 and the shape, density, size, and distribution of the unevenness on the top surface of the substrate 1110 are together adjusted, the radiation angle pattern may be more efficiently controlled.

As shown in FIGS. 4 through 11, the radiation angle pattern of the LED chip may be changed by the shape of the section of the substrate forming the LED chip and the shape of the unevenness on the substrate surface. According to an LED package of the present invention, since a package lens is formed with a shape corresponding to a radiation angle pattern of an LED chip, the optical efficiency is not reduced by a package lens.

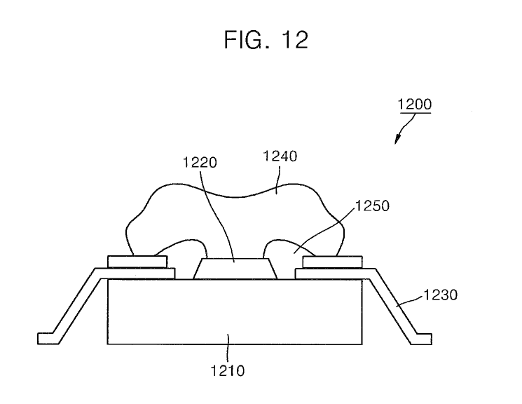

FIG. 12 is a diagram illustrating an LED package according to an exemplary embodiment, in which the side surface of a substrate forming an LED chip inclines to the top surface of the substrate.

Referring to FIG. 12, an LED package 1200 according to the present invention may include a package body 1210, an LED chip 1220, a lead electrode 1230, a package lens 1240, and a filler 1250.

The LED chip 1220 may be mounted on the package body 1210. Also, the package body 1210 may include an upper frame coupled to the lead electrode 1230 and a lower frame located under the LED chip 1220. In this case, the upper frame of the package body 1210 may be formed of plastic, and the lower frame of the package body 1210 may be formed of a conductive material such as aluminum to serve as a heat sink.

The LED chip 1220 may be installed in the package body 1210, and may include a substrate and a light emitting device formed on the substrate. In this case, the shape of the section of the substrate may be a regular trapezoid. Thus, when the shape of the section of the substrate is a regular trapezoid, the LED chip 1220 may have a radiation angle pattern as shown in FIG. 6. The LED chip 1220 may be electrically connected to the lead electrode 1230 on the package body 1210 through a wire.

The package lens 1240 may be installed over the package body 1210 to cover the LED chip 1220. The package lens 1240 may be formed to have a shape corresponding to a radiation angle pattern of the LED chip 1220. Since the radiation angle pattern of the LED chip 1220 is similar to that of FIG. 6, the package lens 1240 may also be formed to have a shape corresponding to the radiation angle pattern shown in FIG. 6. That is, the thickness of a lens of the package lens 1240 is greatest at angles of about 65 degrees and about 325 degrees at which the intensity of radiation of the output light of the LED chip 1220 is greatest. Since the output light in a normal line direction of the LED chip 1220 is relatively smaller, a central portion of the package lens 1240 may have a recessed shape. Thus, when the package lens 1240 is formed to have a shape corresponding to the radiation angle pattern of the LED chip 1220, reduction of the optical efficiency by the package lens 1240 is prevented.

The filler 1250 may be filled between the package lens 1240 and the LED chip 1220, and may be formed of a material such as epoxy or silicon gel. If necessary, phosphor may be mixed in the filler 1250.

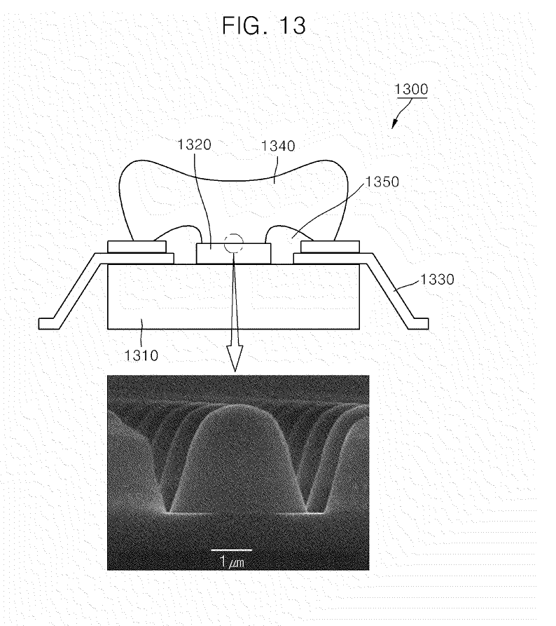

FIG. 13 is a diagram illustrating an LED package according to another exemplary embodiment, in which unevenness is formed on the top surface of a substrate forming an LED chip.

Referring to FIG. 13, an LED package 1300 according to the present invention may include a package body 1310, an LED chip 1320, a lead electrode 1330, a package lens 1340, and a filler 1350.

The LED chip 1320 and the lead electrode 1330 may be mounted on the package body 1310, which corresponds to the package body 1210 of FIG. 12.

The LED chip 1320 may be installed in the package body 1310, and may include a substrate and a light emitting device formed on the substrate. In this case, the shape of the section of the substrate may be rectangular, and an unevenness may be formed on the top surface of the substrate. The unevenness on the top surface of the substrate may have a shape similar to that shown in a SEM photograph of FIG. 13. Since the unevenness have the same shape as the unevenness formed on the top surface of the substrate shown in FIG. 10, the LED chip 1320 may have a radiation angle pattern as shown in FIG. 10. The LED chip 1320 may be electrically connected to the lead electrode 1330 on the package body 1210 through a wire.

The package lens 1340 may be installed over the package body 1310 to cover the LED chip 1320. The package lens 1340 may be formed to have a shape corresponding to a radiation angle pattern of the LED chip 1320. Since the radiation angle pattern of the LED chip 1320 is similar to that of FIG. 10, the package lens 1340 may also be formed to have a shape corresponding to the radiation angle pattern shown in FIG. 10. That is, the thickness of a lens of the package lens 1340 is greatest at angles of about 45 degrees to about 60 degrees and about 300 degrees to about 315 degrees at which the intensity of radiation of the output light of the LED chip 1320 is greatest. Since the output light in a normal line direction of the LED chip 1320 is relatively smaller, a central portion of the package lens 1340 may have a recessed shape. Thus, when the package lens 1340 is formed to have a shape corresponding to the radiation angle pattern of the LED chip 1320, reduction of the optical efficiency by the package lens 1240 is prevented.

The filler 1350 may be filled between the package lens 1340 and the LED chip 1320, and may correspond to the filler 1250 of FIG. 12.

According to embodiments of the present invention, since the shape of a package lens corresponds to a radiation angle pattern of an LED chip, a desired radiation angle pattern can be achieved without a reduction of the optical efficiency even when the package lens is used.

Although the light emitting diode (LED) package including the lens according to the present invention been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A light emitting diode package comprising:
a package body;
a light emitting diode chip installed in the package body; and
a package lens installed in the package body to cover the light emitting diode chip, and formed to have a shape corresponding to a radiation angle pattern of the light emitting diode chip.

2. The light emitting diode package of claim 1, wherein the light emitting diode chip comprises a substrate and a light emitting device disposed on the substrate, and at least one of side surfaces of the substrate inclines to a top surface of the substrate.

3. The light emitting diode package of claim 2, wherein an unevenness is formed on the top surface of the substrate.

4. The light emitting diode package of claim 2, wherein the shape of the section of the substrate is a rectangle, a parallelogram or a trapezoid.

5. The light emitting diode package of claim 2, wherein at least one of the inclination degree and inclination direction of the side surface of the substrate is adjusted to control the radiation angle pattern.

6. The light emitting diode package of claim 3, wherein the shape of the unevenness is a bawl shape, a triangular pyramid shape or a shape of flat top.

7. The light emitting diode package of claim 3, wherein at least one of the size, density, and distribution of the unevenness is adjusted to control the radiation angle pattern.

8. The light emitting diode package of claim 7, wherein the unevenness is densely formed on the substrate to increase the intensity of radiation in the normal line direction of the substrate.

9. The light emitting diode package of claim 1, wherein the thickness of the package lens is greatest at angles at which the intensity of radiation of the output light of the light emitting diode chip is greatest.

10. The light emitting diode package of claim 1, wherein a central portion of the package lens has a recessed shape.
